(19) United States
(12) Patent Application Publication
(10) Pub. No.: US 2014/0060901 A1
(43) Pub. Date: Mar. 6, 2014

(54) TOUCH PANEL

(71) Applicant: SAMSUNG ELECTRO-MECHANICS CO., LTD., Suwon (KR)

(72) Inventor: Hee Soo Kim, Suwon (KR)

(73) Assignee: SAMSUNG ELECTRO-MECHANICS CO., LTD., Suwon (KR)

(21) Appl. No.: 13/686,167

(22) Filed: Nov. 27, 2012

(30) Foreign Application Priority Data
Sep. 3, 2012 (KR) 10-2012-0097334

(51) Int. Cl. H05K 1/02; H05K 1/09

(52) U.S. Cl. CPC H05K 1/0296; H05K 1/092
USPC 174/257; 174/250

(57) ABSTRACT

Disclosed herein is a touch panel including: an electrode pattern configured of a combination of rectangular patterns of which first and second internal angles facing each other are the same as each other and remaining third and fourth internal angles facing each other except for the first and second internal angles are different from each other.

### CROSS REFERENCE TO RELATED APPLICATION

This application claims the benefit of Korean Patent Application No. 10-2012-0097334, filed on Sep. 3, 2012, entitled “Touch Panel”, which is hereby incorporated by reference in its entirety into this application.

### BACKGROUND OF THE INVENTION

1. Technical Field

The present invention relates to a touch panel.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

In accordance with the rapid advancement of an information-oriented society, the use of computers has more and more been widened; however, it is difficult to efficiently operate products using only a keyboard and a mouse currently serving as an input device. Therefore, the necessity for a device that is simple, has less malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of a display such as an electronic organizer, a flat panel display device including a liquid crystal display (LCD) device, a plasma display panel (PDP), an electroluminescence (El) element, or the like, or a cathode ray tube (CRT) to thereby be used to allow a user to select desired information while viewing the display.

In addition, the touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

Meanwhile, in the touch panel, research into a technology of forming an electrode pattern using a metal has been actively conducted, as disclosed in the following Prior Art Document (Patent Document). As described above, when the electrode pattern is made of the metal, electric conductivity is excellent and demand and supply is smooth. However, in the case in which the electrode pattern is made of the metal, the electrode pattern should be formed in a mesh structure in a micrometer (μm) unit in order to prevent users from recognizing the electrode pattern. However, when the electrode pattern of the touch panel is formed in the mesh structure, period characteristics of the electrode pattern of the touch panel and a black matrix pattern of a color filter included in a display (a liquid crystal display (LCD), or the like) are overlapped with each other, such that a Moire phenomenon is generated, thereby deteriorating visibility.

### PRIOR ART DOCUMENT

### Patent Document

(Patent Document 1) KR2010-0091497 A

### SUMMARY OF THE INVENTION

The present invention has been made in an effort to provide a touch panel capable of generating a diffraction image of transmitted light by forming an electrode pattern including a broken line using a rectangular pattern of which two internal angles facing each other are the same as each other and remaining two internal angles facing each other are different from each other.

According to a preferred embodiment of the present invention, there is provided a touch panel including: an electrode pattern configured of a combination of rectangular patterns of which first and second internal angles facing each other are the same as each other and remaining third and fourth internal angles facing each other except for the first and second internal angles are different from each other.

The first internal angle or the second internal angle of one of the two adjacent rectangular patterns may neighbor to the third internal angle or the fourth internal angle of the other rectangular pattern.

The touch panel may further include a transparent substrate having the electrode pattern formed thereon.

The electrode pattern may be made of copper (Cu), aluminum (Al), gold (Au), silver (Ag), titanium (Ti), palladium (Pd), chromium (Cr), or a combination thereof.

The electrode pattern may be made of metal silver formed by exposing/developing a silver salt emulsion layer.

According to another preferred embodiment of the present invention, there is provided a touch panel including: a first electrode pattern configured of a combination of first rectangular patterns of which first and second internal angles facing each other are the same as each other and remaining third and fourth internal angles facing each other except for the first and second internal angles are different from each other; and a second electrode pattern configured of a combination of second rectangular patterns of which fifth and sixth internal angles facing each other are the same as each other and remaining seventh and eighth internal angles facing each other except for the fifth and sixth internal angles are different from each other.

The first internal angle or the second internal angle of one of the two adjacent first rectangular patterns may neighbor to the third internal angle or the fourth internal angle of the other first rectangular pattern, and the fifth internal angle or the sixth internal angle of one of the two adjacent second rectangular patterns may neighbor to the seventh internal angle or the eighth internal angle of the other second rectangular pattern.

The first and second rectangular patterns may be the same as each other.

The center of a virtual line connecting a vertex at which the seventh internal angle of the second rectangular pattern is present and a vertex at which the eighth internal angle of the second rectangular pattern is present to each other may be disposed so as to correspond to a vertex of the first rectangular pattern.

The touch panel may further include a transparent substrate having the first electrode pattern formed on one surface thereof and the second electrode pattern formed on the other surface thereof.

The touch panel may further include: a first transparent substrate having the first electrode pattern formed thereon; and a second transparent substrate having the second electrode pattern formed thereon.

The first electrode pattern or the second electrode pattern may be made of copper (Cu), aluminum (Al), gold (Au), silver (Ag), titanium (Ti), palladium (Pd), chromium (Cr), or a combination thereof.

The first electrode pattern or the second electrode pattern may be made of metal silver formed by exposing/developing a silver salt emulsion layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view of a touch panel according to a first preferred embodiment of the present invention;

FIG. 2 is an enlarged view of the part A shown in FIG. 1;

FIG. 3 is a cross-sectional view of the touch panel shown in FIG. 1;

FIG. 4 is a plan view of a touch panel according to a second preferred embodiment of the present invention;

FIG. 5 is an enlarged view of the part B shown in FIG. 4;

FIG. 6 is an enlarged view of first and second rectangular patterns shown in FIG. 4; and

FIGS. 7 to 9 are cross-sectional views of the touch panel according to the second preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

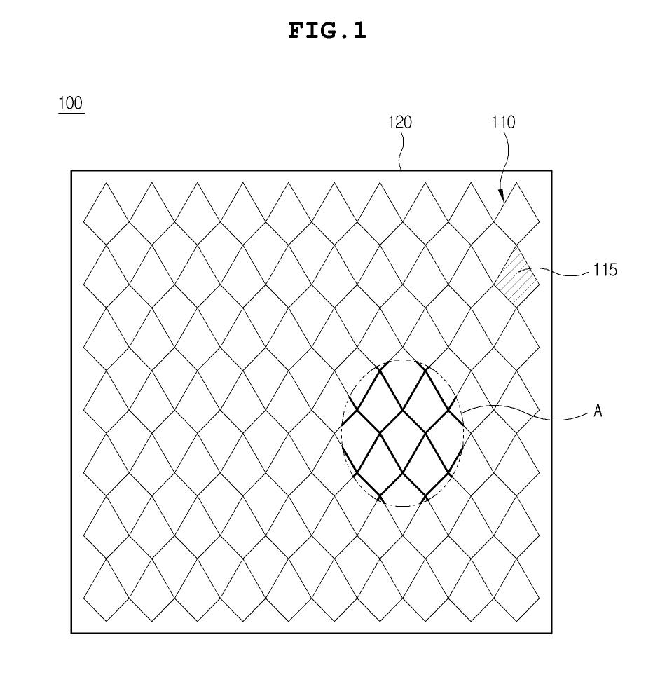

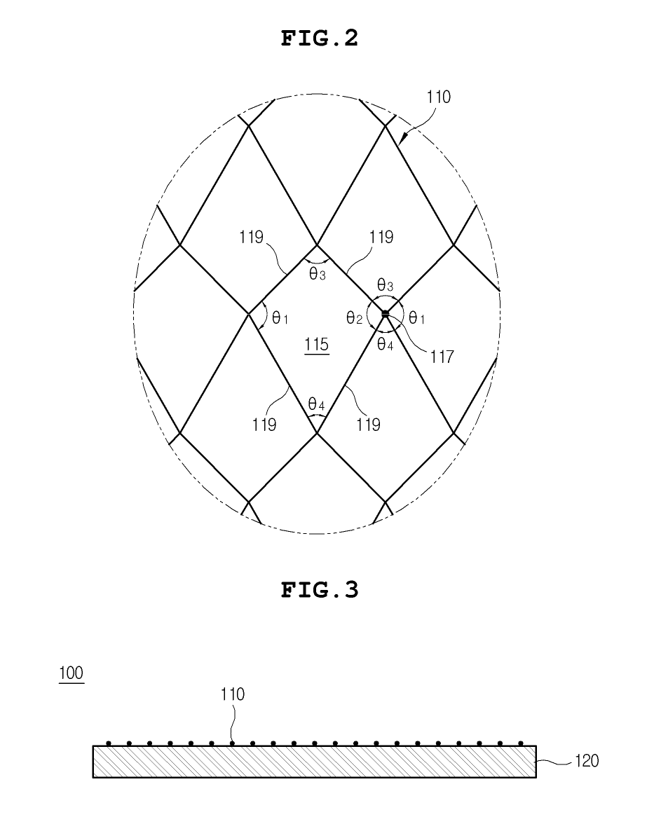

FIG. 1 is a plan view of a touch panel according to a first preferred embodiment of the present invention; and FIG. 2 is an enlarged view of the part A shown in FIG. 1.

As shown in FIGS. 1 and 2, the touch panel 100 according to the present embodiment includes an electrode pattern 110 configured of a combination of rectangular patterns 115 of which first and second internal angles θ₁ and θ₂ facing each other are the same as each other and remaining third and fourth internal angles θ₃ and θ₄ facing each other except for the first and second internal angles θ₁ and θ₂ are different from each other.

The electrode pattern 110 serves to generate a signal at the time of a touch of a user, thereby allowing a controller to recognize a touch coordinate. Here, the electrode pattern 110 may be formed as a micro pattern using copper (Cu), aluminum (Al), gold (Au), silver (Ag), titanium (Ti), palladium (Pd), chromium (Cr), or a combination thereof. In this case, the electrode pattern 110 may be formed by a plating process or a depositing process using a sputter. Meanwhile, in the case in which the electrode pattern 110 is made of a metal such as copper (Cu), a surface of the electrode pattern 110 may be black-oxide treated. Here, the black-oxide treatment indicates treatment in which Cu₂O, CuO, or the like, is precipitated by oxidizing the surface of the electrode pattern 110, wherein the Cu₂ is brown and is thus referred to as a brown oxide and the CuO is black and is thus referred to as a black oxide. As described above, the surface of the electrode pattern 110 is black-oxide treated to prevent light from being reflected, thereby making it possible to improve visibility of the touch panel 100. Further, the electrode pattern 110 may also be made of metal silver formed by exposing and developing a silver salt emulsion layer, in addition to the above-mentioned metal.

In addition, the electrode pattern 100 is patterned according to a predetermined rule. More specifically, the electrode pattern 110 is configured of the combination of rectangular patterns 115 of which the first and second internal angles θ₁ and θ₂ facing each other are the same as each other and the remaining third and fourth internal angles θ₃ and θ₄ facing each other except for the first and second internal angles θ₁ and θ₂ are different from each other. Here, in the rectangular pattern 115, lengths of two sides 119 forming the third internal angle θ₃ are the same as each other, and lengths of two sides 119 forming the fourth internal angle θ₄ are also the same as each other. In addition, the first internal angle θ₁ or the second internal angle θ₂ of one 115 of the two adjacent rectangular patterns 115 neighbors to the third internal angle θ₃ or the fourth internal angle θ₄ of the other rectangular pattern 115. In this case, four adjacent rectangular patterns 115 are disposed to share one vertex 117 with each other. That is, the fourth rectangular patterns 115 are disposed so that the first internal angle θ₁, the second internal angle θ₂, the third internal angle θ₃, and the fourth internal angle θ₄ are formed based on the vertex 117. Here, since the third internal angle θ₃ and the fourth internal angle θ₄ are different from each other, the rectangular pattern 115 includes a broken line formed while passing through the vertex 117. This broken line generates a diffraction image of transmitted light, thereby making it possible to prevent a Moire phenomenon and improve visibility. In addition to the prevention of the Moire phenomenon and the improvement of the visibility, the electrode pattern 110 is basically formed as a straight line, thereby making it possible to more easily manufacture the electrode pattern 110 and more easily calculate an area, or the like, thereof, as compared with the case in which the electrode pattern 110 is formed as a curved line or an arc line. Meanwhile, all of the rectangular patterns 115 configuring the electrode pattern 110 are the same as each other. Therefore, it is possible to prevent a specific portion from being embossed to thereby be recognized by the user.

FIG. 3 is a cross-sectional view of the touch panel shown in FIG. 1. As shown in FIG. 3, the touch panel 100 according to the present embodiment may include a transparent substrate 120 having the electrode pattern 110 formed thereon. Here, the transparent substrate 120 provides a region on which the electrode pattern 110 is to be formed. Here, the transparent substrate 120 needs to have support force capable of supporting the electrode pattern 110 and transparency capable of allowing a user to recognize an image provided by a display. In consideration of the support force and the transparency described above, the transparent substrate 120 may be made of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, tempered glass, or the like, but is not necessarily limited thereto.

Meanwhile, in order to activate one surface of the transparent substrate 120, high frequency treatment or primer treatment may be performed. As described above, one surface of the transparent substrate 120 is activated, thereby making it possible to improve adhesion between the transparent substrate 120 and the electrode pattern 110.

Additionally, an edge of the electrode pattern 110 is provided with an electrode wiring transmitting/receiving an electrical signal to/from the electrode pattern 110. Here, the electrode wiring is formed integrally with the electrode pattern 110, thereby making it possible to simplify a manufacturing process and reduce a lead time. In addition, the electrode wiring and the electrode pattern 110 are formed integrally with each other, thereby making it possible to omit a bonding process between the electrode wiring and the electrode pattern 110. Therefore, it is possible to prevent problems such as a step or a bonding defect between the electrode wiring and the electrode pattern 110 in advance.

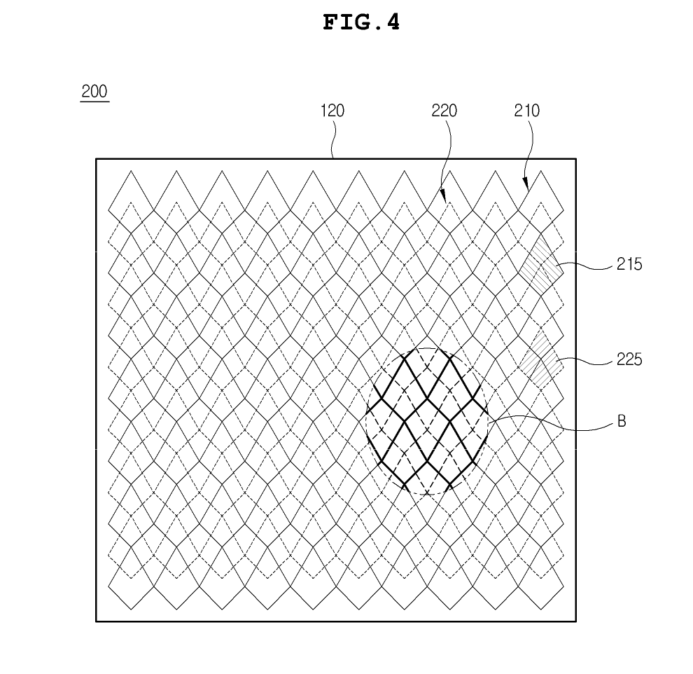

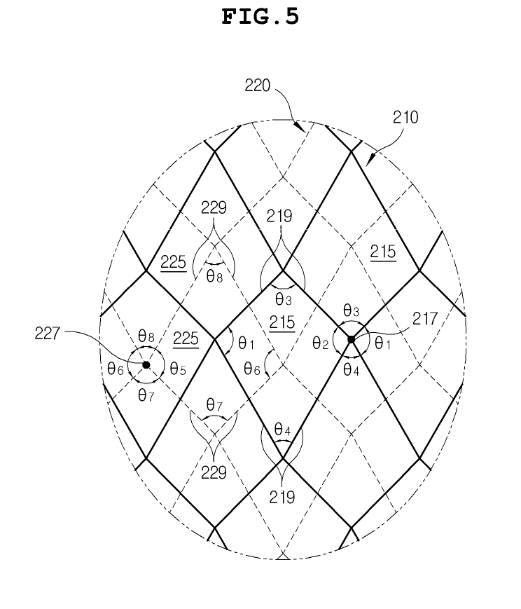

FIG. 4 is a plan view of a touch panel according to a second preferred embodiment of the present invention; and FIG. 5 is an enlarged view of the part B shown in FIG. 4.

As shown in FIGS. 4 and 5, the touch panel 200 according to the present embodiment includes a first electrode pattern 210 configured of a combination of first rectangular patterns 215 of which first and second internal angles θ₁ and θ₂ facing each other are the same as each other and remaining third and fourth internal angles θ₃ and θ₄ facing each other except for the first and second internal angles θ₁ and θ₂ are different from each other; and a second electrode pattern 220 configured of a combination of second rectangular patterns 225 of which fifth and sixth internal angles θ₅ and θ₆ facing each other are the same as each other and remaining seventh and eighth internal angles θ₇ and θ₈ facing each other except for the fifth and sixth internal angles θ₅ and θ₆ are different from each other.

The touch panel 200 according to the present embodiment is different from the touch panel 100 according to the first preferred embodiment of the present invention described above in that it includes two electrode patterns (the first electrode pattern 210 and the second electrode pattern 220). Therefore, in the touch panel 200 according to the present embodiment, a description of portions overlapped with those of the touch panel 100 according to the first preferred embodiment of the present invention will be omitted, and the first and second electrode patterns 210 and 220, and the like, will be mainly described.

The first and second electrode patterns 210 and 220 are patterned according to a predetermined rule. More specifically, the first electrode pattern 210 is configured of the combination of first rectangular patterns 215 of which the first and second internal angles θ₁ and θ₂ facing each other are the same as each other and the remaining third and fourth internal angles θ₃ and θ₄ facing each other except for the first and second internal angles θ₁ and θ₂ are different from each other. In addition, the second electrode pattern 220 is configured of the combination of second rectangular patterns 225 of which the fifth and sixth internal angles θ₅ and θ₆ facing each other are the same as each other and the remaining seventh and eighth internal angles θ₇ and θ₈ facing each other except for the fifth and sixth internal angles θ₅ and θ₆ are different from each other. Here, in the first rectangular pattern 215, lengths of two sides 219 forming the third internal angle θ₃ are the same as each other, and lengths of two sides 219 forming the fourth internal angle θ₄ are also the same as each other. In addition, in the second rectangular pattern 225, lengths of two sides 229 forming the seventh internal angle θ₇ are the same as each other, and lengths of two sides 229 forming the eighth internal angle θ₈ are also the same as each other. Further, the first internal angle θ₁ or the second internal angle θ₂ of one 215 of the two adjacent first rectangular patterns 215 neighbors to the third internal angle θ₃ or the fourth internal angle θ₄ of the other first rectangular pattern 215. In this case, four adjacent first rectangular patterns 215 are disposed to share one vertex 217 with each other. That is, the fourth first rectangular patterns 215 are disposed so that the first internal angle θ₁, the second internal angle θ₂, the third internal angle θ₃, and the fourth internal angle θ₄ are formed based on the vertex 217. Similarly, the fifth internal angle θ₅ or the sixth internal angle θ₆ of one 225 of the two adjacent second rectangular patterns 225 neighbors to the seventh internal angle θ₇ or the eighth internal angle θ₈ of the other second rectangular pattern 225. In this case, four adjacent second rectangular patterns 225 are disposed to share one vertex 227 with each other. That is, the fourth second rectangular patterns 225 are disposed so that the fifth internal angle θ₅, the sixth internal angle θ₆, the seventh internal angle θ₇, and the eighth internal angle θ₈ are formed based on the vertex 227. Here, since the third internal angle θ₃ and the fourth internal angle θ₄ are different from each other, the first rectangular pattern 215 includes a broken line formed while passing through the vertex 217, and since the seventh internal angle θ₇, and the eighth internal angle θ₈ are different from each other, the second rectangular pattern 225 includes a broken line formed while passing through the vertex 227. This broken line generates a diffraction image of transmitted light, thereby making it possible to prevent a moire phenomenon and improve visibility. In addition to the prevention of the Moire phenomenon and the improvement of the visibility, the first and second electrode patterns 210 and 220 are basically formed as a straight line, thereby making it possible to more easily manufacture the first and second electrode patterns 210 and 220 and more easily calculate areas, or the like, thereof, as compared with the case in which the first and second electrode patterns 210 and 220 are formed as a curved line or an arc line. Meanwhile, all of the first rectangular patterns 215 configuring the first electrode pattern 210 are the same as each other, and all of the second rectangular patterns 225 configuring the second electrode pattern 220 are the same as each other. Therefore, it is possible to prevent a specific portion from being embossed to thereby be recognized by the user.

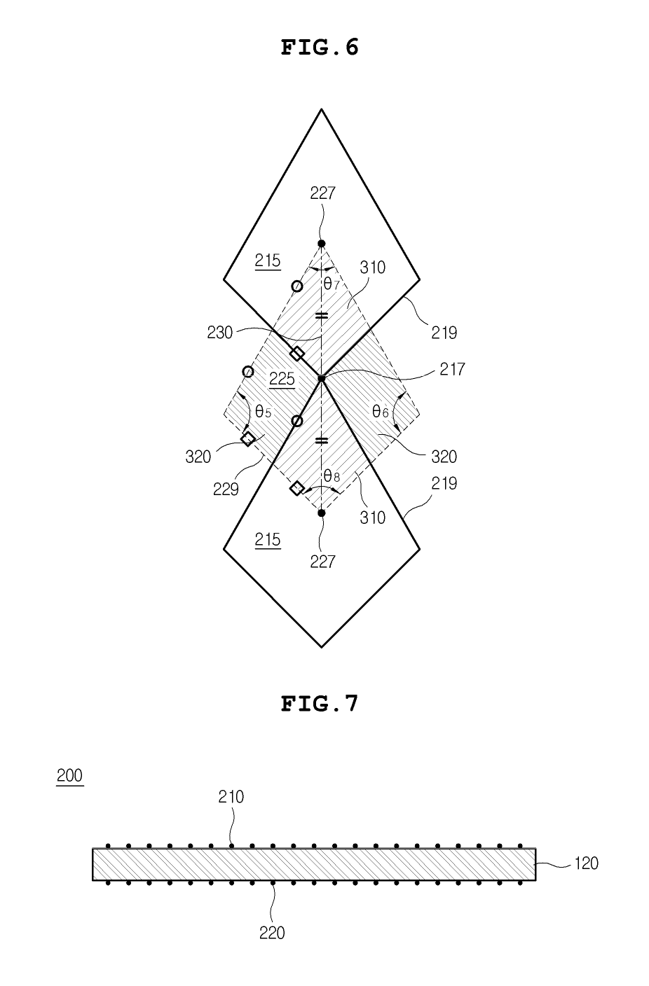

FIG. 6 is an enlarged view of first and second rectangular patterns shown in FIG. 4. As shown in FIG. 6, the first and second rectangular patterns 215 and 225 may be the same as each other. Here, the center of a virtual line 230 connecting the vertex 227 at which the seventh internal angle θ₇ of the second rectangular pattern 225 is present and the vertex 227 at which the eighth internal angle θ₈ of the second rectangular pattern 225 is present to each other may be disposed so as to correspond to the vertex 217 of the first rectangular pattern 215. As described above, the first and second rectangular patterns 215 and 225 are overlapped with each other, such that the second rectangular pattern 225 is divided by sides 219 of the first rectangular pattern 215. Therefore, two virtual third rectangular patterns 310 having the same area are formed, and two virtual fourth rectangular patterns 320 having the same area are formed. Here, since the third rectangular pattern 310 has a shape similar to that of the second rectangular pattern 225 and a length of a side of the third rectangular pattern 310 is a half of the side 229 of the second rectangular pattern 225, an area of the third rectangular pattern 310 is ¼ of an area of the second rectangular pattern 225. Therefore, the two third rectangular patterns 310 occupy a half of the area of the second rectangular pattern 225, and the two fourth rectangular patterns 320 occupy the other half of the area of the second rectangular pattern 225. As a result, since an area of the fourth rectangular pattern 320 is ¼ of the area of the second rectangular pattern 225, the area of the fourth rectangular pattern 320 is the same as that of the third rectangular pattern 310. As described above, since the third rectangular pattern 310 and the fourth rectangular pattern 320 have the same area, even though the first and second rectangular patterns 215 and 225 are overlapped with each other, it is possible to prevent a specific portion from being embossed to thereby be recognized by the user.

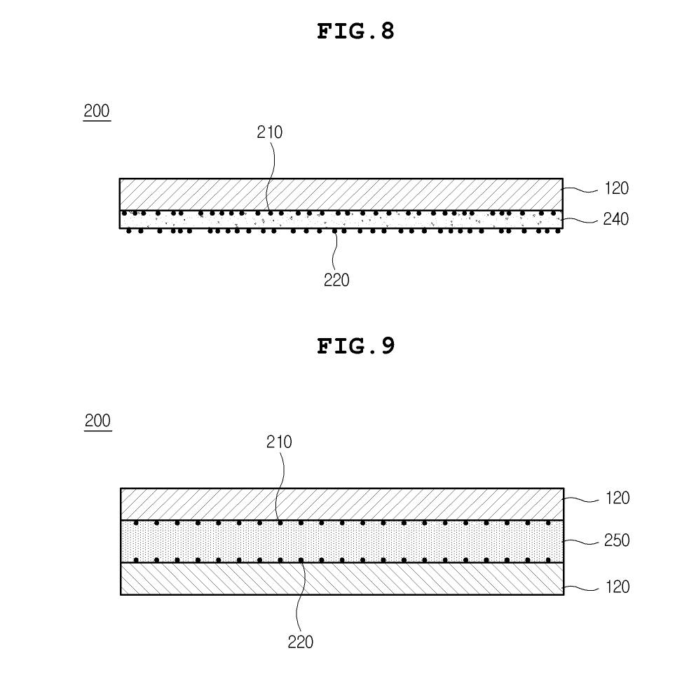

FIGS. 7 to 9 are cross-sectional views of the touch panel according to the second preferred embodiment of the present invention. As shown in FIG. 7, the touch panel 200 according to the present embodiment may include a transparent substrate 120 having the first electrode pattern 210 formed on one surface thereof and the second electrode pattern 220 formed on the other surface thereof. Here, the transparent substrate 120 provides regions on which the first and second electrode patterns 210 and 220 are to be formed. However, the first and second electrode patterns 210 and 220 are not necessarily formed on both surfaces of a single transparent substrate 120. That is, as shown in FIG. 8, after the first electrode pattern 210 is formed on the transparent substrate 120, an insulating layer 240 may be formed on the transparent substrate 120 and the second electrode pattern 220 may be formed on the insulating layer 240. In addition, as shown in FIG. 9, two transparent substrates 120 may be provided, and the first and second electrode patterns 210 and 220 may be formed on the two transparent substrates 120, respectively. In this case, the two transparent substrates 120 may be adhered to each other by an adhesive layer 250.

Additionally, edges of the first and second electrode patterns 210 and 220 may be provided with electrode wirings transmitting/receiving electrical signals to/from the first and second electrode patterns 210 and 220. In this case, the electrode wiring is formed integrally with the first electrode pattern 210 and is formed integrally with the second electrode pattern 220, thereby making it possible to simplify a manufacturing process and reduce a lead time. In addition, the electrode wirings and the first and second electrode patterns 210 and 220 are formed integrally with each other, thereby making it possible to omit a bonding process between the electrode wirings and the first and second electrode patterns 210 and 220. Therefore, it is possible to prevent problems such as a step or a bonding defect between the electrode wiring and the first and second electrode patterns 210 and 220 in advance.

According to the preferred embodiments of the present invention, the electrode pattern including the broken line using the rectangular pattern of which the two internal angles facing each other are the same as each other and the remaining two internal angles facing each other are different from each other, thereby making it possible to generate the diffraction image of the transmitted light. Therefore, it is possible to prevent the Moire phenomenon and improve the visibility.

In addition, according to the preferred embodiments of the present invention, the electrode pattern is formed as the straight line, thereby making it possible to more easily manufacture the electrode pattern and more easily calculate an area, or the like, thereof, as compared with the case in which the electrode pattern is formed as the curved line or the arc line.

Further, according to the preferred embodiments of the present invention, even though the two layer electrode patterns are overlapped with each other, all of the areas of virtual rectangular patterns formed as the overlapped electrode patterns are the same as each other, thereby making it possible to prevent a specific portion from being embossed to thereby be recognized by the user.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel comprising:
an electrode pattern configured of a combination of rectangular patterns of which first and second internal angles facing each other are the same as each other and remaining third and fourth internal angles facing each other except for the first and second internal angles are different from each other.

2. The touch panel as set forth in claim 1, wherein the first internal angle or the second internal angle of one of the two adjacent rectangular patterns neighbors to the third internal angle or the fourth internal angle of the other rectangular pattern.

3. The touch panel as set forth in claim 1, further comprising a transparent substrate having the electrode pattern formed thereon.

4. The touch panel as set forth in claim 1, wherein the electrode pattern is made of copper (Cu), aluminum (Al), gold (Au), silver (Ag), titanium (Ti), palladium (Pd), chromium (Cr), or a combination thereof.

5. The touch panel as set forth in claim 1, wherein the electrode pattern is made of metal silver formed by exposing/developing a silver salt emulsion layer.

6. A touch panel comprising:
a first electrode pattern configured of a combination of first rectangular patterns of which first and second internal angles facing each other are the same as each other and remaining third and fourth internal angles facing each other except for the first and second internal angles are different from each other; and
a second electrode pattern configured of a combination of second rectangular patterns of which fifth and sixth internal angles facing each other are the same as each other and remaining seventh and eighth internal angles facing each other except for the fifth and sixth internal angles are different from each other.

7. The touch panel as set forth in claim 6, wherein the first internal angle or the second internal angle of one of the two adjacent first rectangular patterns neighbors to the third internal angle or the fourth internal angle of the other first rectangular pattern, and
the fifth internal angle or the sixth internal angle of one of the two adjacent second rectangular patterns neighbors to the seventh internal angle or the eighth internal angle of the other second rectangular pattern.

8. The touch panel as set forth in claim 6, wherein the first and second rectangular patterns are the same as each other.

9. The touch panel as set forth in claim 8, wherein the center of a virtual line connecting a vertex at which the seventh internal angle of the second rectangular pattern is present and a vertex at which the eighth internal angle of the second rectangular pattern is present to each other is disposed so as to correspond to a vertex of the first rectangular pattern.

10. The touch panel as set forth in claim 6, further comprising a transparent substrate having the first electrode pattern formed on one surface thereof and the second electrode pattern formed on the other surface thereof.

11. The touch panel as set forth in claim 6, further comprising:
a first transparent substrate having the first electrode pattern formed thereon; and
a second transparent substrate having the second electrode pattern formed thereon.

12. The touch panel as set forth in claim 6, wherein the first electrode pattern or the second electrode pattern is made of copper (Cu), aluminum (Al), gold (Au), silver (Ag), titanium (Ti), palladium (Pd), chromium (Cr), or a combination thereof.

13. The touch panel as set forth in claim 6, wherein the first electrode pattern or the second electrode pattern is made of metal silver formed by exposing/developing a silver salt emulsion layer.
